(19) United States
(12) Patent Application Publication
(10) Pub. No.: US 2026/0282841 A1
(43) Pub. Date: Sep. 17, 2026

(54) FIXTURE DEVICE

(71) Applicant: ALL RING TECH CO., LTD., Kaohsiung City (TW)

(72) Inventors: Tai-Hung LIU, Kaohsiung City (TW); Chien-Min LIU, Kaohsiung City (TW)

(21) Appl. No.: 19/331,571

(22) Filed: Sep. 17, 2025

(30) Foreign Application Priority Data
Mar. 12, 2025 (TW) 114109201

(51) Int. Cl. H01L 21/683; H01L 21/67; H01L 21/673; H01L 21/687

(52) U.S. Cl. CPC H10P 72/78; H10P 72/0446; H10P 72/13; H10P 72/7624

(57) ABSTRACT

A fixture device is adapted to, in a pressing process of a heat dissipation cover of a workpiece, position the workpiece. The fixture device includes a mold seat unit, a mold block, and a secure member. The mold block is disposed on the mold seat unit, and is adapted to hold the workpiece. The secure member secures the mold block on the mold seat unit. The secure member has a passage that is adapted for gas to flow therethrough to position the workpiece on the mold block.

### CROSS-REFERENCE TO RELATED APPLICATION

This application claims priority to Taiwanese Invention Patent Application No. 114109201, filed on Mar. 12, 2025, the entire disclosure of which is incorporated by reference herein.

### FIELD

The disclosure relates to a fixture device, and more particularly to a fixture device that is adapted to, in a pressing process of a workpiece (specifically, a process of pressing a heat dissipation cover against a chip), position the workpiece.

### BACKGROUND

A conventional fixture device is used to hold a chip carrying a heat dissipation cover, and includes a mold seat unit, a mold block disposed on the mold seat unit and being rectangular, and a plurality of pressing members securing the mold block to the mold seat unit.

The mold block is used to support the chip in the process of pressing the heat dissipation cover, in order to facilitate the heat dissipation cover being pressed against the chip. The mold block has a vacuum hole located at the center thereof, to form a negative pressure environment on a surface of the mold block, thereby drawing and positioning the chip carrying the heat dissipation cover. Each of the pressing members is threadedly connected to the mold seat unit by a fastener and abuts against an outer peripheral portion of the mold block, thereby securing the mold block to the mold seat unit.

Since the chip has to be heated in the process of pressing the heat dissipation cover, the mold block may have a thermal expansion phenomenon. At this time, since the outer ring portion of the mold block is restricted by abutment of the pressing members, the expansion degree of the outer ring portion of the mold block is limited. However, the center of the mold block is not restricted, so the expansion degree of the center of the mold block may be greater than that of the outer ring portion of the mold block, causing the center of the mold block to bulge, resulting in a poor pressing effect. Additionally, the conventional fixture device does not have an integrated design in structure, which needs to be improved.

### SUMMARY

Therefore, an object of the disclosure is to provide a fixture device that can alleviate at least one of the drawbacks of the prior art.

According to the disclosure, the fixture device is adapted to, in a pressing process of a heat dissipation cover of a workpiece, position the workpiece. The fixture device includes a mold seat unit, a mold block, and a secure member. The mold block is disposed on the mold seat unit, and is adapted to hold the workpiece. The secure member secures the mold block on the mold seat unit. The secure member has a passage that is adapted for gas to flow therethrough to position the workpiece on the mold block.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is an exploded perspective view of a workpiece and a boat for use with a fixture device of the present disclosure.

FIG. 2 is a perspective view illustrating a first embodiment of the fixture device according to the disclosure carrying the boat and the workpiece.

FIG. 3 is a partly-exploded perspective view illustrating one of mold blocks of the first embodiment being separated from one of thermal insulation members of the first embodiment.

FIG. 4 is another partly-exploded perspective view of the first embodiment.

FIG. 5 is a fragmentary sectional view of the first embodiment.

FIG. 6 is a perspective view illustrating a second embodiment of the fixture device according to the disclosure being used with the first embodiment.

FIG. 7 is a fragmentary sectional view of the second embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

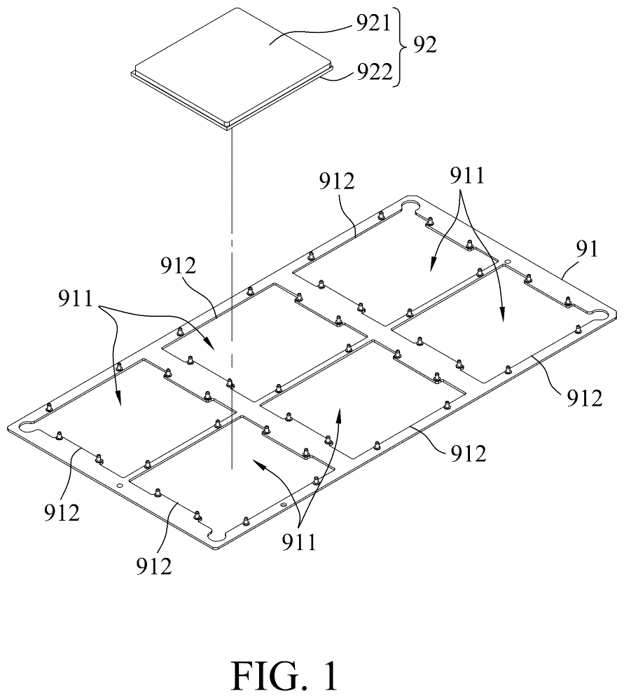

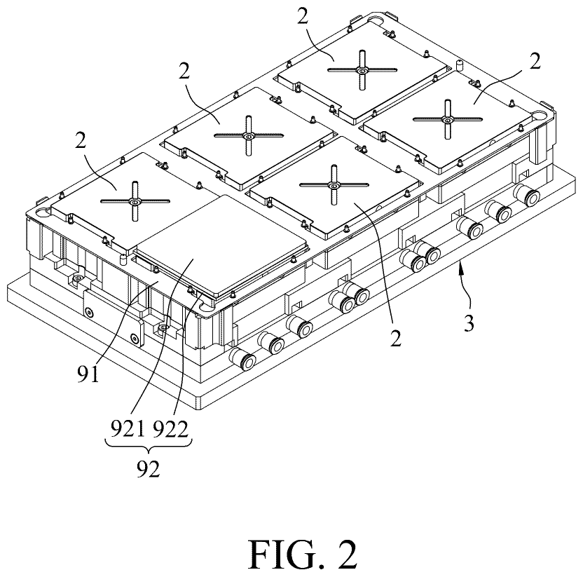

Referring to FIGS. 1 to 3, a first embodiment of a fixture device according to the disclosure shown in FIG. 2 is exemplified as a bottom fixture device, and is adapted to, in a pressing process of a heat dissipation cover of a workpiece, position the workpiece. The first embodiment is for use with a rectangular boat 91 and multiple workpieces 92 (only one is shown in FIG. 1) disposed on the boat 91. Each of the workpieces 92 has a heat dissipation cover 921, and a chip 922 carrying the heat dissipation cover 921.

The boat 91 carries the workpieces 92 so as to facilitate pressing the heat dissipation covers 921 on the chips 922. The boat 91 has multiple placement areas 911 on which the workpieces 92 are respectively disposed, and multiple rectangular openings 912 which respectively correspond in position to the placement areas 911.

Since the configurations of the workpieces 92 are the same, only one of the workpieces 92 is shown in the drawings.

The fixture device includes a mold seat unit 3, multiple mold blocks 2 disposed on the mold seat unit 3, and multiple secure units 4 respectively securing the mold blocks 2 on the mold seat unit 3.

The mold blocks 2 are adapted to hold the workpieces 92, respectively. Specifically, in the first embodiment, each of the mold blocks 2 supports the chip 922 of the respective workpiece 92. Each of the mold blocks 2 is in a shape of a cuboid, and is made of a material that has relatively great thermal conductivity, e.g., aluminum. The mold blocks 2 may be dimensioned to respectively extend through the openings 912 of the boat 91, and each of the mold blocks 2 has a heating member (not shown) for heating the respective workpiece 92 and a sensor (not shown) for sensing temperature thereof.

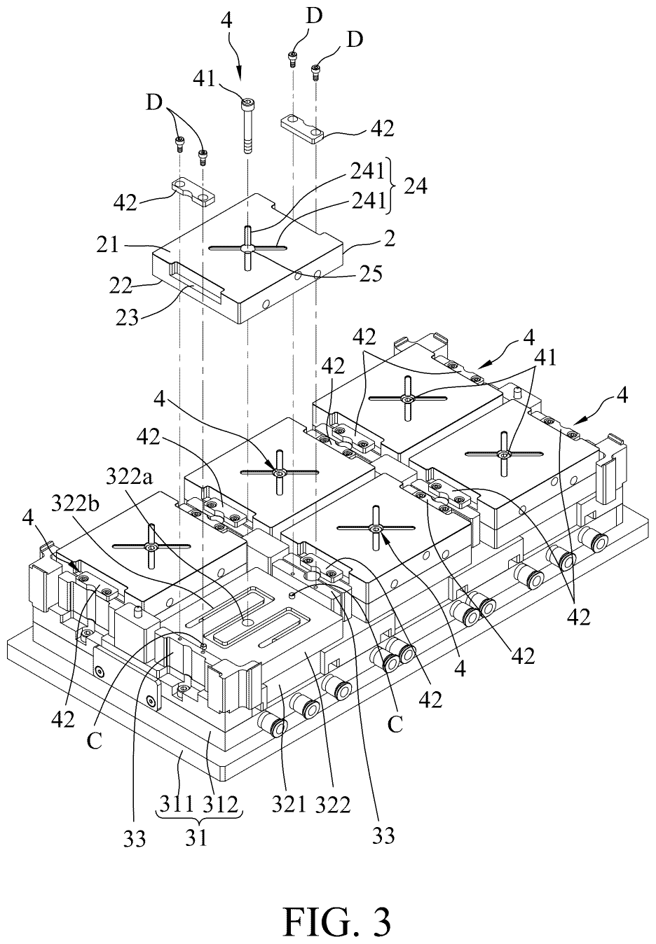

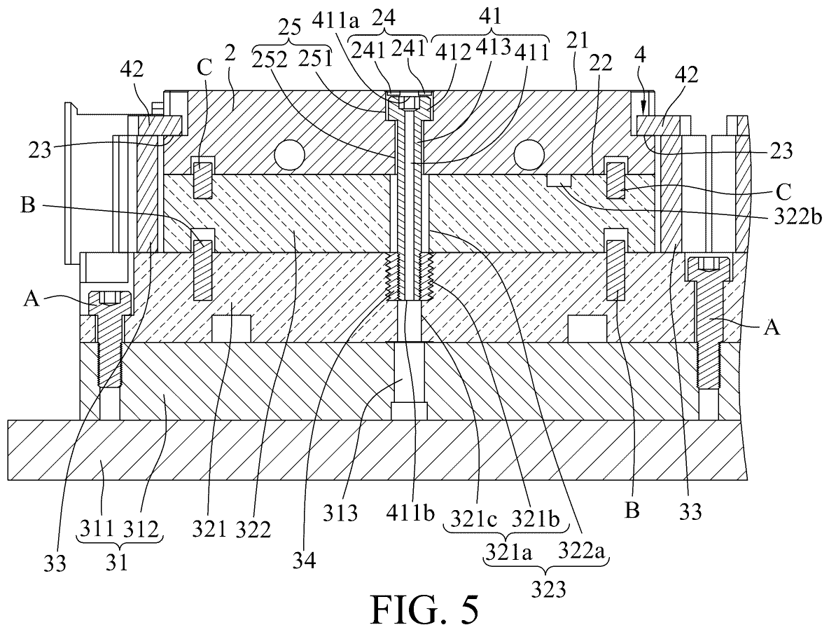

Referring to FIGS. 3 to 5, each of the mold blocks 2 has an operation surface 21 that faces upward and that is adapted to support the respective workpiece 92, an opposite surface 22 that is opposite to the operation surface 21, a plurality of secure surfaces 23 (see FIG. 5) that are located between the operation surface 21 and the opposite surface 22, a gas groove 24 that is formed in the operation surface 21, and a first insertion hole 25 that extends through the operation surface 21 and the opposite surface 22 and that is in spatial communication with the gas groove 24. In this embodiment, each of the mold blocks 2 has two secure surfaces 23, but is not limited to such. For the sake of brevity, only one mold block 2 will be described in the following.

The secure surfaces 23 are respectively located on two opposite sides of the operation surface 21, and are lower than the operation surface 21 in height.

The gas groove 24 has a plurality of groove portions 241 that intersect one another to form an X shape, and an intersection of the groove portions 241 is located at a central portion of the mold block 2 (specifically, at the center of the mold block 2). In this embodiment, the gas groove 24 has two groove portions 241, and each of the groove portions 241 is in a form of a straight line and extends obliquely to form the X shape with the other groove portion 241.

The first insertion hole 25 has a head segment 251 and a body segment 252 that are in spatial communication with each other. A width of the head segment 251 is greater than a width of the body segment 252, and the head segment 251 is in spatial communication with the intersection of the groove portions 241 of the gas groove 24.

The mold seat unit 3 has a bottom seat subunit 31, a thermal insulation subunit 32 that is disposed on the bottom seat subunit 31, multiple secure seats 33 that are disposed on the thermal insulation subunit 32, and multiple sleeve members 34 (only one is shown) that are located in the thermal insulation subunit 32.

The bottom seat subunit 31 includes a base seat 311 that is in a shape of a rectangular plate, and a gas flow seat 312 that is disposed on the base seat 311 and that is in a shape of a rectangular plate.

The gas flow seat 312 of the bottom seat subunit 31 defines multiple airways 313 that are adapted for gas to flow therethrough, and multiple gas valves 314 through which a gas source is in spatial communication with the airways 313.

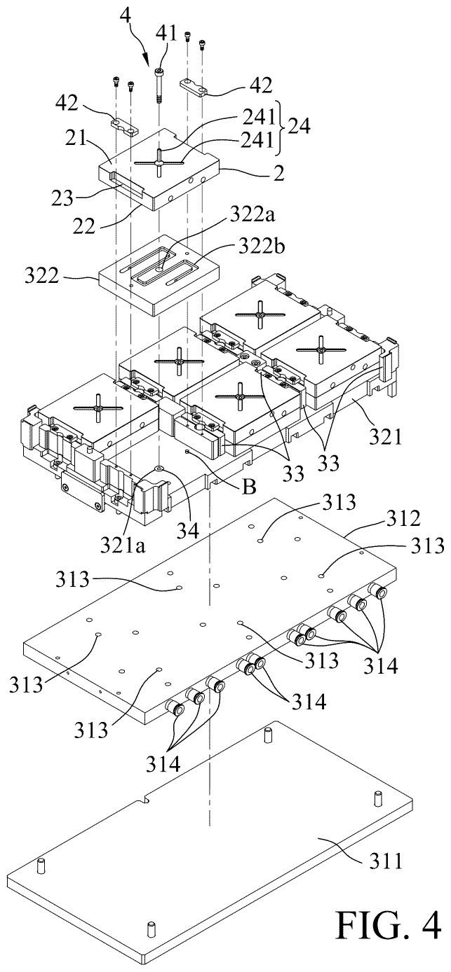

The thermal insulation subunit 32 supports the mold block 2 (i.e., the mold block 2 is disposed on the thermal insulation subunit 32), and is made of a material that has relatively small thermal conductivity, e.g., glass fiber. The thermal insulation subunit 32 has a thermal insulation seat 321 that is in a shape of a rectangular plate, multiple thermal insulation members 322 (only one can be seen in FIG. 4) which are disposed on the thermal insulation seat 321 and each of which is in a shape of a cuboid, and multiple second insertion holes 323 which are defined by the thermal insulation seat 321 and the thermal insulation members 322, and each of which includes an orifice 322a and an aperture 321a.

The thermal insulation seat 321 is threadedly connected to the gas flow seat 312 by multiple fastener members (A) (see FIG. 5), and the apertures 321a (only one is indicated in FIG. 4) of the second insertion holes 323 are formed in the thermal insulation seat 321 and are respectively in spatial communication with the airways 313. Each of the apertures 321a has a wide portion 321b in which a respective sleeve member 34 is located, and a narrow portion 321c that is in spatial communication with and located between the wide portion 321b and the respective airway 313.

Referring to FIGS. 4 and 5, the mold blocks 2 are respectively disposed on the thermal insulation members 322 of the thermal insulation subunit 32. Each of the thermal insulation members 322 is positioned on the thermal insulation seat 321 in directions transverse to a top-bottom direction by multiple first pins (B), and is positioned relative to the respective mold block 2 in the directions transverse to the top-bottom direction by multiple second pins (C). The orifices 322a of the second insertion holes 323 are respectively formed in and extend through central portions of the thermal insulation members 322, and each of the thermal insulation members 322 has a recess groove 322b that is formed in a top surface of the thermal insulation member 322.

For each of the second insertion holes 323, the orifice 322a is in spatial communication with the wide portion 321b of the aperture 321a. The orifice 322a of each of the second insertion holes 323 is in spatial communication with the first insertion hole 25 of the respective mold block 2 (i.e., each of the second insertion holes 323 is in spatial communication with the first insertion hole 25 of the respective mold block 2).

For each of the thermal insulation members 322, the recess groove 322b is configured as a serpentine groove as shown in FIG. 4, and is spaced apart from the orifice 322a.

The secure seats 33 are disposed on the thermal insulation seat 321, and come in pairs. Each pair of the secure seats 33 correspond in position to a respective mold block 2; specifically, the secure seats 33 in each pair are respectively located on two opposite sides of the respective mold block 2.

Each of the sleeve members 34 threadedly engages the wide portion 321b of the respective apertures 321a, and has an inner surface that is threaded. In some examples, each of the sleeve members 34 may be configured as a threaded bushing.

The secure units 4 each include a secure member 41 and multiple press members 42.

The secure member 41 of each of the secure units 4 is in the shape of a bolt, and is inserted in the respective mold block 2, a respective thermal insulation member 322 and the thermal insulation seat 321, so that each of the mold blocks 2 is secured on the respective thermal insulation member 322 of the mold seat unit 3. The secure member 41 of each of the secure units 4 is inserted in the central portion of the respective mold block 2. In the first embodiment, the secure member 41 of each of the secure units 4 is inserted into the central portion of the respective mold block 2 and the thermal insulation subunit 32 from the intersection of the groove portions 241 of the respective mold block 2. The secure member 41 of each of the secure units 4 has a passage 411 that extends in the top-bottom direction and that is adapted for gas to flow therethrough to thereby position a respective workpiece 92 on the respective mold block 2, and a head portion 412 and a body portion 413 that cooperatively define the passage 411. For the sake of brevity, only one secure unit 4 is described in the following.

The passage 411 has a first passage opening 411a that is located on a top end of the passage 411 and that is defined by the head portion 412, and a second passage opening 411b that is located on a bottom end of the passage 411 and that is opposite to the first passage opening 411a. The first passage opening 411a is equal to or lower than a top end of the first insertion hole 25 and the operation surface 21 in height in the top-bottom direction. The first passage opening 411a is in spatial communication with the head segment 251 of the first insertion hole 25 and the intersection of the groove portions 241 of the gas groove 24. The body portion 413 defines the second passage opening 411b. The secure member 41 (specifically, the second passage opening 411b of the secure member 41) is spaced apart from a respective airway 313 by a respective second insertion hole 323, and is in spatial communication with the respective airway 313 through the narrow portion 321c of the respective second insertion hole 323. Specifically, the second passage opening 411b is in spatial communication with the respective airway 313.

A width of the head portion 412 is greater than a width of the body portion 413, and the head portion 412 is inserted in the head segment 251 of the first insertion hole 25 of the respective mold block 2. A thickness of the head portion 412 in the top-bottom direction is smaller than a depth of the head segment 251 of the first insertion hole 25 of the respective mold block 2 in the top-bottom direction, so that the head portion 412 is lower than and non-coplanar with the operation surface 21 of the respective mold block 2.

The body portion 413 is inserted in the mold block 2 and the mold seat unit 3; specifically, the body portion 413 extends through the body segment 252 of the first insertion hole 25, and extends through the respective second insertion hole 323. Specifically, the body portion 413 is inserted in the orifice 322a of the respective thermal insulation member 322, and is threadedly connected to a respective sleeve member 34 located in the wide portion 321b of the aperture 321a of the respective second insertion hole 323. A bottom part of the body portion 413 is threadedly connected to the respective sleeve member 34. The bottom part of the body portion 413 does not extend into the narrow portion 321c of the aperture 321a of the respective second insertion hole 323, so that the secure member 41 is spaced apart from the respective airway 313.

In this embodiment, each of the secure units 4 includes two press members 42, and for each of the secure units 4, the press members 42 abut against opposite sides of a periphery of the respective mold block 2 and cooperate with the secure member 41 to secure the respective mold block 2 on the respective thermal insulation member 322 and the thermal insulation seat 321. For each of the secure units 4, the press members 42 are spaced apart from the secure member 41, so that the central portion and the periphery (i.e., the secure surfaces 23) of the respective mold block 2 are secured. Specifically, the press members 42 respectively abut against the secure surfaces 23 of the respective mold block 2; a portion of each press member 42 abuts against the respective one of the secure surfaces 23 of the respective mold block 2, and the other portion of each press member 42 is threadedly connected to, by multiple fastener members (D) (see FIG. 3), a respective one of the secure seats 33 in the respective pair to which the mold block 2 corresponds in position.

In practice, the mold block 2 is in a negative pressure state when gas is evacuated through the passage 411; that is, the gas is evacuated from the passage 411 (specifically, the first and second passage openings 411a, 411b) through the narrow portion 321c of the aperture 321a of the respective second insertion hole 323, the respective airway 313 and the gas valves 314, so that a negative pressure environment is formed on the operation surface 21 of the mold block 2, thereby attracting the respective workpiece 92 on the mold block 2.

One advantageous effect of the first embodiment is the innovative design of the secure units 4 where the functions of securing the workpieces 92 on the mold blocks 2 and securing the mold blocks 2 on the mold seat unit 3 (i.e., combination of the passage 411, the head portion 412 and the body portion 413) are integrated into one component. In addition, the structure is simplified.

Another advantageous effect of the first embodiment is that, besides the press members 42 securing the periphery of the mold block 2, the secure member 41 can further secure the central portion of the mold block 2, so that the central portion of the mold block 2 is prevented from bulging relative to the periphery of the mold block 2, and thus pressing effect of the first embodiment is improved.

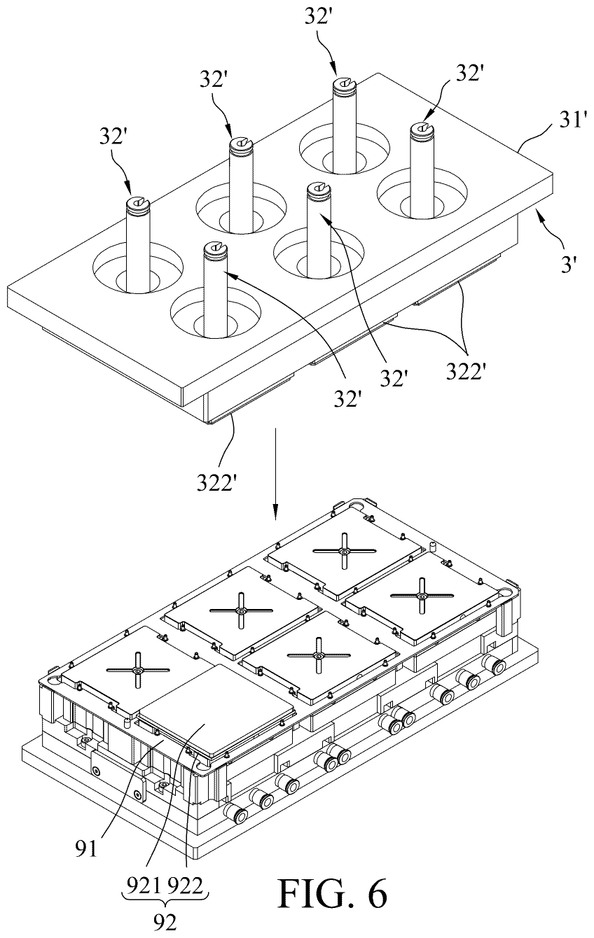

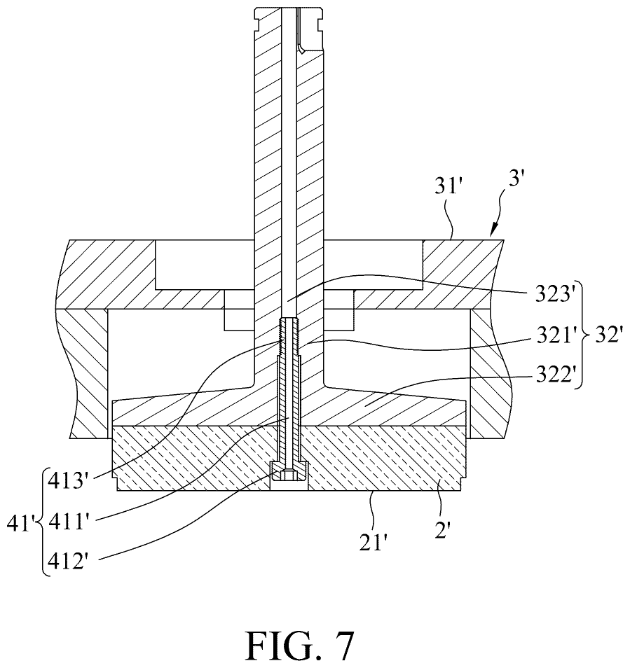

Referring to FIGS. 6 and 7, a second embodiment of the fixture device according to the disclosure is exemplified as a top fixture device, and is adapted to, in a pressing process of a heat dissipation cover of a workpiece, be used with the first embodiment. In an example, the first embodiment positions and supports the workpieces 92, and the second embodiment positions and presses the heat dissipation covers 921 toward the chips 922. The second embodiment includes a mold seat unit 3′, multiple mold blocks 2′ disposed on the mold seat unit 3′, and multiple secure members 41′ respectively securing the mold blocks 2′ on the mold seat unit 3′. Since the connections between the mold blocks 2′ and the secure members 41′ are the same, only one mold block 2′ and one secure member 41′ are illustrated in the following (see FIG. 7) for the sake of brevity.

The mold block 2′ is in a shape of a cuboid and has an operation surface 21′.

The mold seat unit 3′ includes a top seat subunit 31′ that is substantially in a shape of a rectangular plate, and multiple abutment members 32′ that are inserted in the top seat subunit 31′.

Each of the abutment members 32′ is able to be driven to move in the top-bottom direction relative to the top seat subunit 31′, and has a rod portion 321′ and a block portion 322′ that is integrally connected to a bottom of the rod portion 321′. The block portion 322′ and the rod portion 321′ of each of the abutment members 32′ cooperatively define a gas flow channel 323′. The mold blocks 2′ are respectively disposed on the abutment members 32′ (specifically, the block portions 322′ of the abutment members 32′). In practice, each of the abutment members 32′ is driven to urge the respective mold block 2′ to press the heat dissipation cover 921 of a respective workpiece 92 toward the chip 922 of the respective workpiece 92. The abutment members 32′ may be driven by, for example, a piston rod of a pneumatic cylinder that presses top ends of the rod portions 321′ downward.

The secure member 41′ secures the mold block 2′ on a respective abutment member 32′, and has a passage 411′, and a head portion 412′ and a body portion 413′ that cooperatively define the passage 411′.

The head portion 412′ is located at the bottom and is inserted in the mold block 2′, and the body portion 413′ is located at the top and extends into the block portion 322′ and the rod portion 321′ of the respective abutment member 32′. The passage 411′ is in spatial communication with the gas flow channel 323′ of the respective abutment member 32′.

In practice, after the mold blocks 2′ press the heat dissipation covers 921 toward the chips 922, through gas being supplied into the gas flow channels 323′ and the passages 411′, a positive pressure environment is formed on the operation surface 21′ of each of the mold blocks 2′, so that the heat dissipation covers 921 are detached from the mold blocks 2′, thereby ensuring that the heat dissipation covers 921 are coupled to the chips 922 instead of the mold blocks 2′ after the pressing process.

An advantageous effect of the second embodiment is the innovative design of the secure members 41′, which combines the securing and detaching functions in one-piece. In addition, the structure is simplified.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A fixture device adapted to, in a pressing process of a heat dissipation cover of a workpiece, position the workpiece, and comprising:
a mold seat unit;
a mold block disposed on said mold seat unit, and adapted to hold the workpiece; and
a secure member securing said mold block to said mold seat unit,
wherein said secure member has a passage that is adapted for gas to flow therethrough to position the workpiece on said mold block.

2. The fixture device as claimed in claim 1, wherein said mold block is in a negative pressure state when the gas is evacuated through said passage.

3. The fixture device as claimed in claim 1, wherein said mold block has an operation surface that is adapted to support the workpiece, and a first insertion hole that extends through said operation surface and in which said secure member is inserted, said passage of said secure member having a first passage opening through which the gas is adapted to be evacuated so as to form a negative pressure environment on said operation surface of said mold block.

4. The fixture device as claimed in claim 3, wherein said mold seat unit has a second insertion hole that is in spatial communication with said first insertion hole and in which said secure member is inserted, and an airway that is in spatial communication with said second insertion hole and that is spaced apart from said secure member, said airway being in spatial communication with a second passage opening of said passage that is opposite to said first passage opening, the gas being adapted to be evacuated from said passage through said airway.

5. The fixture device as claimed in claim 4, wherein said mold seat unit further has a bottom seat subunit, and a thermal insulation subunit that is disposed on said bottom seat subunit, said bottom seat subunit defining said airway, said thermal insulation subunit defining said second insertion hole, said mold block being disposed on said thermal insulation subunit.

6. The fixture device as claimed in claim 4, wherein said mold seat unit further has a sleeve member that is located in said second insertion hole, said secure member further having a head portion that is inserted in said first insertion hole, and a body portion that extends through said first insertion hole and that is threadedly connected to said sleeve member.

7. The fixture device as claimed in claim 3, wherein said secure member further has a head portion and a body portion that cooperatively define said passage, said head portion being inserted in said mold block and defining said first passage opening, said first passage opening being equal to or lower than a top end of said first insertion hole and said operation surface in height, said body portion being inserted in said mold block and said mold seat unit.

8. The fixture device as claimed in claim 3, wherein said mold block further has a gas groove that is formed in said operation surface and that is in spatial communication with said first insertion hole and said first passage opening.

9. The fixture device as claimed in claim 8, wherein said gas groove has a plurality of groove portions that intersect one another, and an intersection of said plurality of groove portions is in spatial communication with said first insertion hole and said first passage opening.

10. The fixture device as claimed in claim 3, the workpiece being disposed on a boat, the boat having a placement area on which the workpiece is disposed, and an opening which corresponds in position to the placement area, wherein said mold block is adapted to extend through the opening.

11. The fixture device as claimed in claim 1, wherein said secure member is inserted in a central portion of said mold block.

12. The fixture device as claimed in claim 11, further comprising a plurality of press members that abut against a periphery of said mold block to secure said mold block on said mold seat unit, said plurality of press members being spaced apart from said secure member.

13. The fixture device as claimed in claim 12, wherein said mold block has an operation surface that is adapted to support the workpiece, an opposite surface that is opposite to said operation surface, and a plurality of secure surfaces that are located between said operation surface and said opposite surface, said plurality of press members respectively abutting against said plurality of secure surfaces.
